(19) United States
(12) Patent Application Publication
(10) Pub. No.: US 2020/0384500 A1
(43) Pub. Date: Dec. 10, 2020

(54) UV LIGHT IRRADIATION METHOD

(71) Applicant: Sharp Kabushiki Kaisha, Sakai City, Osaka (JP)

(72) Inventor: Masaki HIRUOKA, Sakai City (JP)

(21) Appl. No.: 16/477,913

(22) PCT Filed: Sep. 29, 2017
(86) PCT No.: PCT/JP2017/035416

§ 371 Date: Jul. 15, 2019

(51) Int. Cl. B05D 3/06

(52) U.S. Cl. CPC B05D 3/067; G03F 7/70716

(57) ABSTRACT

Provided is a UV light irradiation device. A support pin supports an irradiated body when the irradiated body is irradiated with UV light, and a difference in a UV light reflectance between a tip portion of the support pin and a surface of a stage is equal to or smaller than 1%.

### TECHNICAL FIELD

The disclosure relates to a UV light irradiation device and a UV light irradiation method.

### BACKGROUND ART

At the time of manufacturing industrial products and the like, UV light irradiation is performed to various target objects in various steps in some cases. At the time of the UV light irradiation, it is required that an effect of the UV light irradiation be exerted evenly over an irradiated region.

### CITATION LIST

### Patent Literature

PTL 1: JP 2014-80348 A (published on May 8, 2014).

### SUMMARY

### Technical Problem

The disclosure has an object to exert an effect of UV light irradiation evenly over an irradiated region.

### Solution to Problem

A UV light irradiation device according to one aspect of the disclosure includes a stage, a support pin, and a UV light source. The support pin is configured to support an irradiated body away from the stage when the irradiated body is irradiated with UV light. A difference in a UV light reflectance between a tip portion of the support pin and a surface of the stage is equal to or smaller than 1%.

A UV light irradiation device according to one aspect of the disclosure includes a stage, a support pin, and a UV light source. The support pin is configured to support an irradiated body away from the stage when the irradiated body is irradiated with UV light. A position of the irradiated body is capable of being changed with respect to the support pin.

A UV light irradiation method according to one aspect of the disclosure is a method for irradiating an irradiated body with UV light. The method includes arranging the irradiated body on a support pin or a stage, supporting the irradiated body with the support pin and separating the irradiated body away from the stage, and irradiating the irradiated body with UV light while moving the irradiated body with respect to the support pin under a state in which the irradiated body is away from the stage.

### Advantageous Effects of Disclosure

According to one aspect of the disclosure, the effect of the UV light irradiation can be exerted evenly over the irradiated region.

### BRIEF DESCRIPTION OF DRAWINGS

FIG. 1 is a view for illustrating an outline of a UV light irradiation device according to a first embodiment of the disclosure.

FIG. 2 is a view for illustrating an outline of the UV light irradiation device having another configuration according to the first embodiment.

FIG. 3 is a view for illustrating an outline of a UV light irradiation device according to a second embodiment of the disclosure.

FIG. 4 is a view for illustrating an outline of a support pin in the second embodiment.

FIG. 5 is a view for illustrating an outline of a UV light irradiation device according to a third embodiment of the disclosure.

FIG. 6 is a view for illustrating an outline of a support pin having another configuration.

FIG. 7 is a view for illustrating an outline of a known UV light irradiation device.

### DESCRIPTION OF EMBODIMENTS

### Known UV Light Irradiation Device

Before the description of Embodiments of the disclosure, a known UV light irradiation device is described. This is for easy understanding of the disclosure.

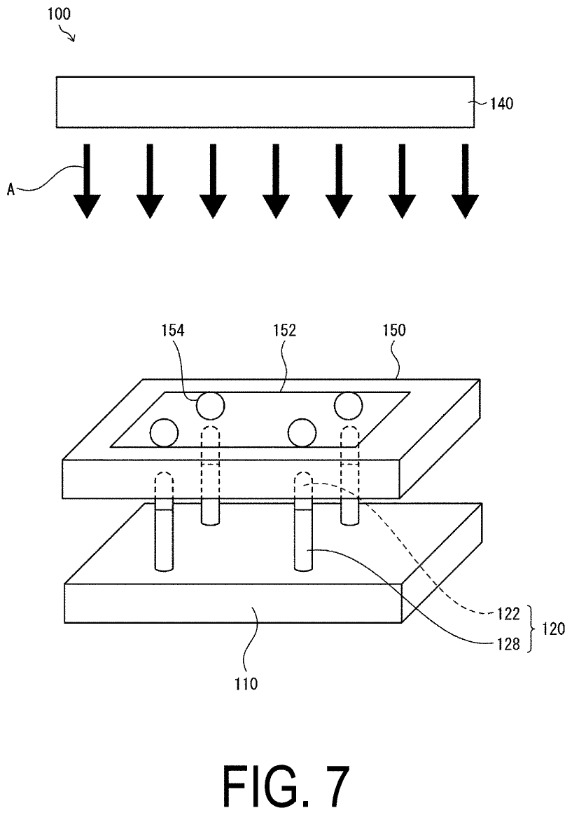

FIG. 7 is a view for illustrating a schematic configuration of a known UV light irradiation device 100. In FIG. 7, a state in which an irradiated region 152 of an irradiated body 150 is irradiated with UV light (arrow A) is illustrated.

### Usage Example of UV Light Irradiation Device

Note that, the UV light irradiation device can be used in manufacturing steps for various products. As an example, a manufacturing step for a display element, especially a flexible display element can be exemplified. As an example of the flexible display element, an organic EL display can be exemplified.

In the manufacturing step for an organic EL display, a flat light-transmissive substrate can be exemplified as a UV light-irradiated body. A photocurable resin is applied to the light-transmissive substrate by, for example, ink-jet application. Further, the UV light irradiation device is used for curing the photocurable resin. By curing the resin, for example, a sealing film is formed in the organic EL display.

### Steps

The UV light irradiation device 100 includes a stage 110, support pins 120, and a UV light source 140. The support pins 120 are provided to the stage 110 in a movable manner in an up-and-down direction. Here, an upper direction indicates a direction from the stage 110 to the UV light source 140. The support pins 120 protrude from the stage 110 and are stored in the stage 110 by moving in the up-and-down direction. For example, when the irradiated body 150 is arranged on the UV light irradiation device 100, the support pins 120 are stored in the stage 110. With this, under a state in which no protrusions exist on a surface 112 of the stage 110, the irradiated body 150 can be arranged on the stage 110. For example, in the step of manufacturing the organic EL display device described above, a light-transmissive substrate to be an organic EL display is placed as the irradiated body 150 on the stage 110 by a robot hand. Note that, a photocurable resin is applied to the light-transmissive substrate in advance.

Subsequently, the irradiated body 150 is irradiated with the UV light. Before the irradiation, the support pins 120 are caused to protrude upward from the stage 110. With this, under a state in which a lower surface of the irradiated body 150 and the surface 112 of the stage 110 are away from each other and a gap is formed between the irradiated body 150 and the stage 110, the irradiated body 150 is irradiated with the UV light.

Here, the irradiated body 150 floats above the stage 110 in order to prevent heat unevenness. When the stage 110 and the irradiated body 150 are brought into contact with each other, heat unevenness is caused. Accordingly, a finished result of the photocurable resin (film thickness and the like) is unsatisfactory. In order to avoid this problem, the irradiated body 150 floats above the stage 110 through the use of the support pins 120.

In the case of UV light irradiation performed by the known UV light irradiation device 100, there is a problem in that an effect of the UV light irradiation is less likely to be exerted evenly over the irradiated region 152. Specifically, an uneven part 154, in which an effect of the UV light irradiation is weak or strong, is liable to be generated in the irradiated region 152 of the irradiated body 150.

The uneven part 154 is liable to be caused at positions corresponding to the support pins 120 in the irradiated region 152. This is because of a difference in UV light reflectance between the support pins 120 and the surface 112 of the stage 110.

Meanwhile, in a case where the irradiated body 150 is a light-transmissive substrate, irradiation is performed with the UV light reflected on the stage 110 for the photocurable resin. That is, the UV light passes through a back surface of the transparent irradiated body 150 and reaches the photocurable resin. Here, the presence or absence of the UV light passing through the back surface of the irradiated body 150 depends on the presence or absence of the support pin 120, and this difference leads to a problem. Note that, the number of the support pins 120 is determined by a size of the irradiated body 150.

As illustrated in FIG. 7, the support pin 120 includes a pin trunk portion 128 and a pin tip portion 122 being a tip portion of the support pin 120. Here, in general, the tip portion 122 is formed by a polyether-ether-ketone (PEEK) resin, a polysulphone (PSE) resin, or the like.

Meanwhile, in general, the surface 112 of the stage 110 is subjected to anti-reflection processing such as black plating.

Here, a resin such as a PEEK resin and a PSF resin and the surface subjected to the anti-reflection processing such as black plating have different UV light reflectance. Thus, in the irradiated region 152, the UV light irradiation amount of the portions corresponding to the support pins 120 and that of the other portions are different from each other. Accordingly, the uneven part 154 is generated.

For example, in the case where the resin applied to the irradiated body 150 is cured by the UV light irradiation, a curing rate differs from that of the other portions in the uneven part 154. As a result, the film thickness of the resin differs.

### First Embodiment

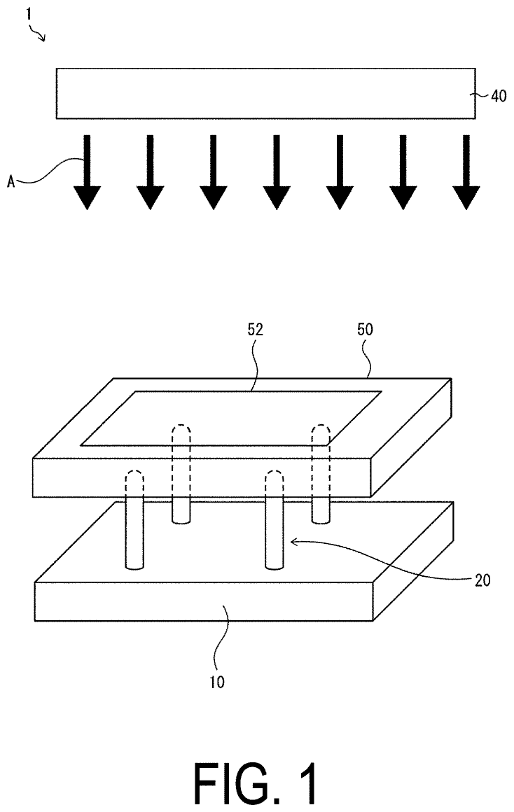

Now, with reference to FIG. 1, a UV light irradiation device 1 according to the first embodiment of the disclosure is described. FIG. 1 is a view for illustrating an outline of the UV light irradiation device 1 according to the first embodiment of the disclosure.

In the UV light irradiation device 1 illustrated in FIG. 1, a stage 10 and support pins 20 are formed of the same material. Thus, in an irradiated region 52 of an irradiated body 50, a portion having different reflectance of the UV light (A) emitted from a UV light source 40 is not present in a lower part of the irradiated body 50. Thus, generation of the uneven part 154 can be suppressed.

### Other Configurations

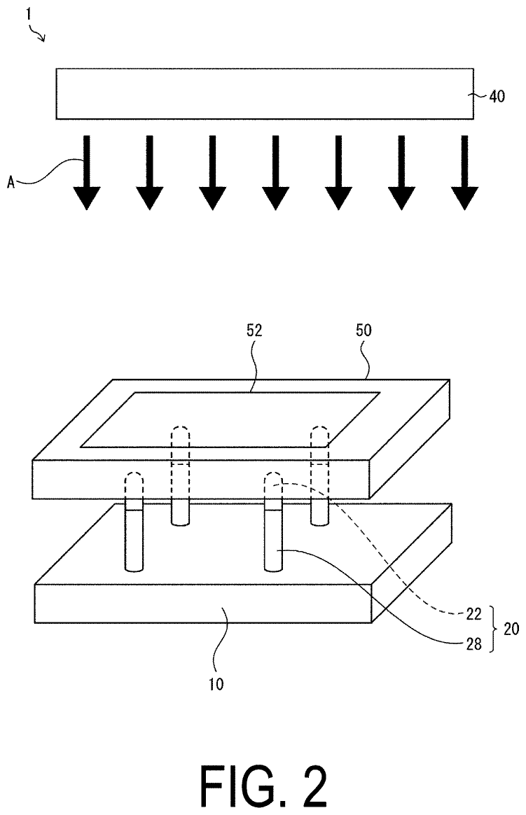

Next, with reference to FIG. 2, other configurations of the UV light irradiation device 1 according to the first embodiment are described. FIG. 2 is a view for illustrating an outline of the UV light irradiation device 1 having another configuration according to the first embodiment.

In the previous description, the example in which the stage 10 and the support pins 20 are formed of the same material is given. However, the stage 10 and the support pins 20 are not necessarily required to be formed of the same material. It is only required that the stage 10 and the support pins 20 have surfaces with close UV light reflectance, which are oriented to the irradiated body 50. Now, an example is given in the following description.

In the UV light irradiation device 1 illustrated in FIG. 2, the support pin 20 is divided into a pin trunk portion 28 and a pin tip portion 22. The pin tip portion 22 of the support pin 20 is near a portion being contact with the irradiated body 50.

Normally, the stage 10 has a surface subjected to surface processing such as black plating for the purpose of anti-reflection. In the UV light irradiation device 1 illustrated in FIG. 2, the pin tip portion 22 is subjected to the same surface processing to which the stage 10 is subjected. With this, the stage 10 and the support pins 20 have the surface with the same UV light reflectance, which are oriented to the irradiated body 50. Thus, in the irradiated region 52 of the irradiated body 50, a portion having different reflectance is not present in the lower part of the irradiated body 50. Thus, generation of the uneven part 154 can be suppressed.

Note that, the target portion of the support pin 20, which is subjected to the surface processing, is not limited to the pin tip portion 22 and may be the entire support pin 20 including the pin trunk portion 28.

Further, the stage 10 and the support pins 20 do not necessarily need to have the surfaces with the same UV light reflectance, which are oriented to the irradiated body 50. For example, a difference of the reflectance is only required to be equal to or smaller than 1%.

### Second Embodiment

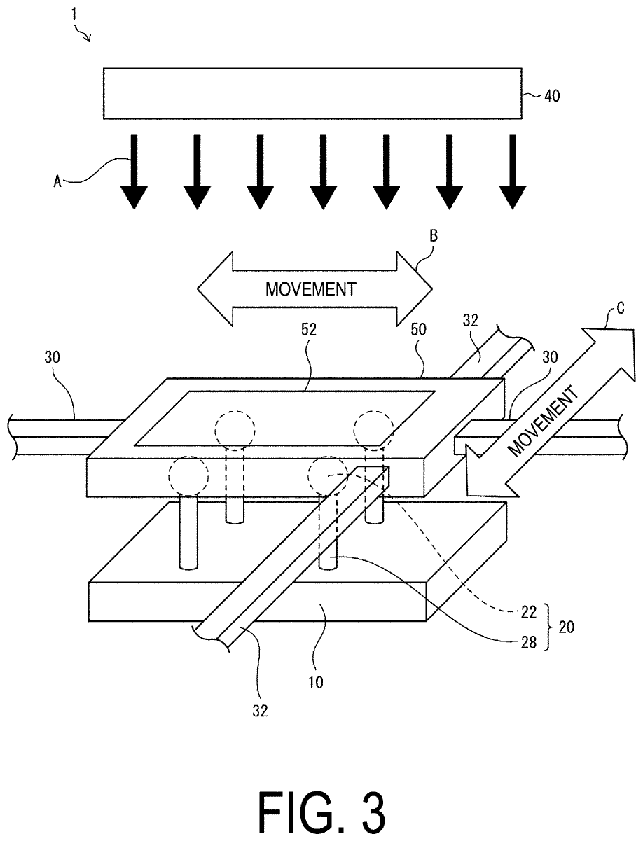

Next, with reference to FIG. 3, the UV light irradiation device 1 according to the second embodiment of the disclosure is described. FIG. 3 is a view for illustrating an outline of the UV light irradiation device 1 according to the second embodiment of the disclosure.

The UV light irradiation device 1 according to the second embodiment is different from the UV light irradiation device 1 according to the first embodiment in that the irradiated body 50 arranged on the support pins 20 is movable in a plane direction of the irradiated body 50. Specifically, balls are provided to the pin tip portion 22 of the support pin 20. Those balls cause the irradiated body 50 arranged on the support pins 20 to move easily. Further, irradiated-body moving portions for causing the irradiated body 50 on the support pins 20 to move are provided.

### Pin Tip Portion

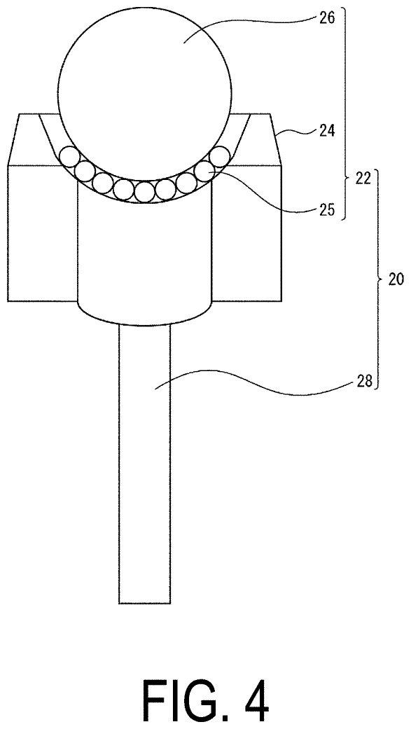

With reference to FIG. 4, the support pin 20 in the second embodiment is described. FIG. 4 is a view for illustrating an outline of the support pin 20 in the second embodiment.

The balls for causing the irradiated body 50 arranged on the support pins 20 to move easily are provided to the pin tip portion 22 being a tip portion of the support pin 20. Specifically, a ball receiver 24, auxiliary balls 25, and a main ball 26 are provided to the pin tip portion 22. The ball receiver 24 functions as a pedestal for the auxiliary balls 25 and the main ball 26 and has a shape hollowed out in a substantially semi-spherical shape. Firstly, a plurality of auxiliary balls 25 having a small diameter are arranged in the ball receiver 24. On the auxiliary balls 25, one main ball 26 is arranged. The balls having different diameters are arranged in two stages. Accordingly, the main ball 26 can be rotated more smoothly.

### Irradiated-Body Moving Portions

As illustrated in FIG. 3, first irradiated-body moving portions 30 and second irradiated-body moving portions 32 are provided to the UV light irradiation device 1 according to the second embodiment. Specifically, two irradiated-body moving portions are provided to the irradiated body 50 in each of a right-and-left direction (direction of the arrow B) and a front-and-rear direction (direction of the arrow C). That is, the respective irradiated-body moving portions are provided to four sides of the irradiated body 50. Further, the first irradiated-body moving portions 30 and the second irradiated-body moving portions 32 are movable in the right-and-left direction (direction of the arrow B) and the front-and-rear direction (direction of the arrow C), respectively. With this configuration, when the irradiated body 50 is moved in the right direction, one irradiated-body moving portion pushes the irradiated body 50. On the contrary, when the irradiated body 50 is moved in the left direction, the other irradiated-body moving portion pushes the irradiated body 50. In this configuration, it is only required that tip portions of the irradiated-body moving portions be in abutment with the irradiated body 50. That is, the irradiated body 50 can be moved in the right-and-left direction and the front-and-rear direction by the four arms (irradiated-body moving portions).

With this, by moving the first irradiated-body moving portions 30 and/or the second irradiated-body moving portions 32, the irradiated body 50 can be moved on the support pins 20 in the right-and-left direction and/or the front-and-rear direction.

### Actions

After the irradiated body 50 is arranged on the stage 10 or the support pins 20, the irradiated body 50 is irradiated with the UV light (arrow A) under a state in which the irradiated body 50 is supported by the support pins 20. At this state, the irradiated body 50 is not fixed to a certain position, but can be moved (slightly moved). Specifically, by moving the first irradiated-body moving portions 30 and/or the second irradiated-body moving portions 32, the irradiated body 50 is moved. At this state, because the main ball 26 and the like are provided to the support pin 20, the irradiated body 50 is moved smoothly on the support pins 20.

Further, by moving the irradiated body 50 at the time of UV light irradiation, the positions at which the support pins 20 are brought into contact with the irradiated body 50 can be changed. With this, even when the support pins 20 and the stage 10 have different UV light reflectance, an uneven part caused by strength of the UV light irradiation is less liable to be generated. This is because the influence of the support pin 20 is not fixed to one position but is dispersed.

### Other Configurations

Note that, in addition to the configuration illustrated in FIG. 3, other configurations of the irradiated-body moving portions are conceivable.

For example, in the configuration illustrated in FIG. 3, the irradiated body 50 are movable in two directions, which are the right-and-left directions and the front-and-rear directions. The irradiated body 50 can be moved in one direction. In this case, the irradiated-body moving portions may be any of the first irradiated-body moving portions 30 and the second irradiated-body moving portions 32.

Further, in the configuration illustrated in FIG. 3, the four irradiated-body moving portions are provided. However, one irradiated-body moving portion may be provided. With this configuration, for example, it is conceivable that the irradiated-body moving portions are configured to be robot arms so that the tip portions of the irradiated-body moving portions can move the irradiated body 50 in both the right-and-left direction (direction of the arrow B) and the front-and-rear direction (direction of the arrow C).

### Third Embodiment

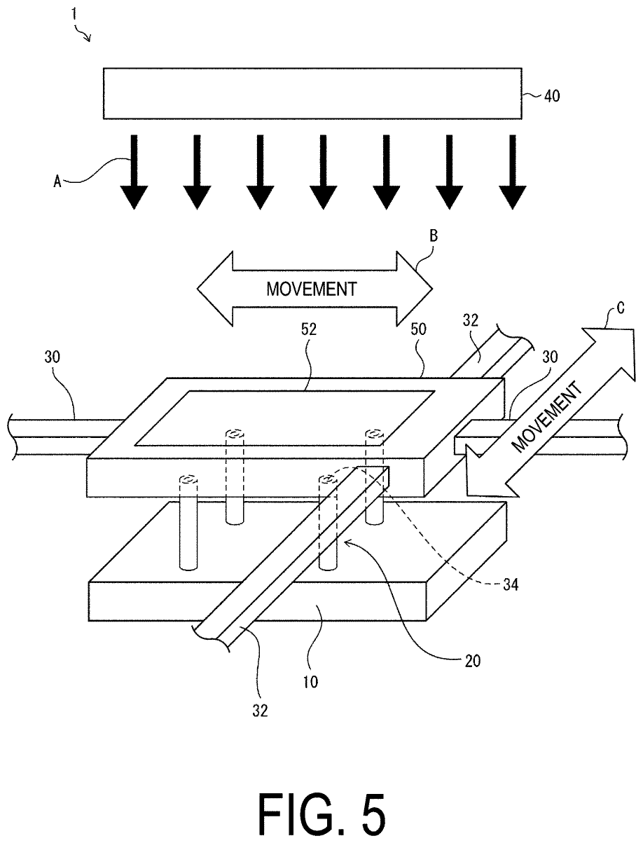

Next, with reference to FIG. 5, the UV light irradiation device 1 according to the third embodiment of the disclosure is described. FIG. 5 is a view for illustrating an outline of the UV light irradiation device 1 according to the third embodiment of the disclosure.

The UV light irradiation device 1 according to the third embodiment is different from the UV light irradiation device 1 according to the second embodiment in that an air outlet 34 is provided in a tip of the support pin 20 in place of the balls. Specifically, in the second embodiment, the irradiated body 50 is brought into contact with the support pins 20 through intermediation with the balls. In contrast, in the third embodiment, an air jetted from the air outlet 34 causes the irradiated body 50 to float above the support pins 20.

### Pin Tip Portion

With reference to FIG. 5, the support pin 20 in the third embodiment is described. FIG. 5 is a view for illustrating an outline of the UV light irradiation device 1 according to the third embodiment.

The air outlet 34 is provided in the tip portion of the support pin 20. An air such as nitrogen gas can be blown out from the air outlet 34. By jetting air from the air outlet 34, the irradiated body 50 can be caused to float above the support pins 20. The irradiated body 50 is not brought into contact with the support pins 20. Accordingly, over the support pins 20 (space above the support pins 20), the irradiated body 50 can easily be moved.

### Actions

After the irradiated body 50 is arranged on the stage 10 or the support pins 20, the irradiated body 50 is irradiated with the UV light (arrow A) under a state in which the irradiated body 50 is supported by the support pins 20. At this state, the irradiated body 50 is not fixed to a certain position, but can be moved (slightly moved). Specifically, by moving the first irradiated-body moving portions 30 and/or the second irradiated-body moving portions 32, the irradiated body 50 is moved. At this time, the jetted air can cause the irradiated body 50 not to be brought into contact with the support pins 20 because the air outlet 34 is provided in the support pin 20. Thus, the irradiated body 50 can be smoothly moved.

Further, by moving the irradiated body 50 at the time of UV light irradiation, the positions at which the support pins 20 are brought into contact with the irradiated body 50 can be changed. With this, even when the support pins 20 and the stage 10 have different UV light reflectance, an uneven part caused by strength of the UV light irradiation is less liable to be generated. This is because the influence of the support pin 20 is not fixed to one position but is dispersed.

### Irradiated-Body Moving Portions

The configuration of the irradiated-body moving portions may be the configuration illustrated in FIG. 5. The configuration of the irradiated-body moving portions illustrated in FIG. 5 is similar to the configuration illustrated in FIG. 3 in the second embodiment. Thus, the description thereof is omitted herein.

Further, the configuration of the irradiated-body moving portions is not limited to the configuration illustrated in FIG. 3. For example, the irradiated-body moving portions having another configuration illustrated in the third embodiment can be applied.

### Examples of Applied Products

The UV light irradiation device 1 according to this embodiment can be used in manufacturing steps for various products. For example, the disclosure can be used for a manufacturing step for a display element, particularly a flexible display element. As the display element, a light emitting element in which luminance and transmittance are controlled by an electric current is exemplified. Specifically, examples of the light emitting element include an organic electro luminescence (EL) display provided with an organic light emitting diode (OLED), an EL display such as an inorganic EL display provided with an inorganic light emitting diode, and a quantum dot light emitting diode (QLED) display provided with a QLED.

### Combination and the Like

The disclosure is not limited to the embodiments stated above. Embodiments obtained by appropriately combining technical approaches stated in each of the different embodiments also fall within the scope of the technology of the disclosure. Moreover, novel technical features may be formed by combining the technical approaches stated in each of the embodiments.

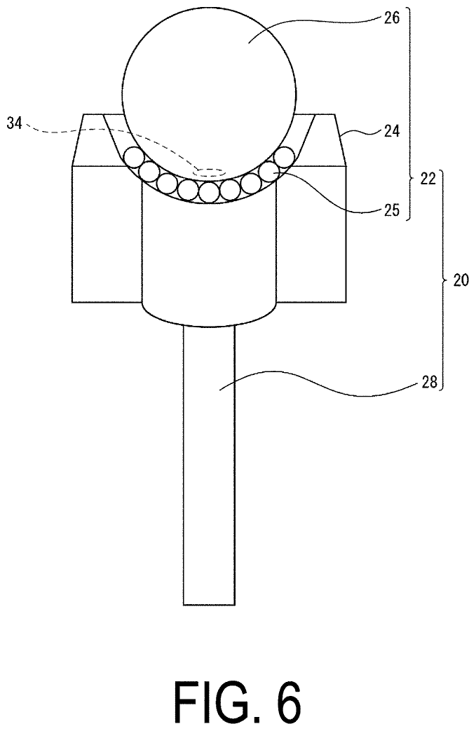

For example, as in FIG. 6 for illustrating other configurations of the support pin 20, in addition to the air outlet 34 provided in the tip of the support pin 20, the balls can be arranged. Specifically, the plurality of auxiliary balls 25 are arranged between the air outlet 34 and the main ball 26. Further, the air blown out from the air outlet 34 rotates the auxiliary balls 25. With this, the following configuration is conceivable. That is, together with the rotation of the auxiliary balls 25, the main ball 26 is rotated, and the irradiated body 50 is easily moved with respect to the support pins 20.

### Supplement

A UV light irradiation device according to a first aspect of the disclosure includes a stage, a support pin, and a UV light source. The support pin is configured to support an irradiated body away from the stage when the irradiated body is irradiated with UV light. A difference of a UV light reflectance between a tip portion of the support pin and a surface of the stage is equal to or smaller than 1%. p In the UV light irradiation device according to a second aspect of the disclosure, the tip portion and the surface are formed of the same material.

In the UV light irradiation device according to a third aspect of the disclosure, the tip portion and the surface are subjected to similar surface processing.

In the UV light irradiation device according to a fourth aspect of the disclosure, the surface processing is anti-reflection processing with black plating.

In the UV light irradiation device according to a fifth aspect of the disclosure, the support pin allows the position of the irradiated body to be changed with respect to the support pin.

A UV light irradiation device according to a sixth aspect of the disclosure includes a stage, a support pin, and a UV light source. The support pin is configured to support an irradiated body away from the stage when the irradiated body is irradiated with UV light. A position of the irradiated body is capable of being changed with respect to the support pin.

In the UV light irradiation device according to a seventh aspect of the disclosure, a ball, which is brought into contact with the irradiated body and is rotatable, is provided to a tip portion of the support pin.

In the UV light irradiation device according to an eighth aspect of the disclosure, an outlet of air is provided in the tip portion of the support pin. The support pin and the irradiated body are prevented to be brought into contact with each other through the intermediation of the air.

The UV light irradiation device according to a ninth aspect of the disclosure further includes an irradiated-body moving portion configured to change a position of the irradiated body supported by the support pin.

In the UV light irradiation device according to a tenth aspect of the disclosure, the irradiated body is a light-transmissive substrate.

A UV light irradiation method according to an eleventh aspect of the disclosure is a method for irradiating an irradiated body with UV light. The method includes arranging the irradiated body on a support pin or a stage, supporting the irradiated body with the support pin and separating the irradiated body away from the stage, and irradiating the irradiated body with UV light while moving the irradiated body with respect to the support pin under a state in which the irradiated body is away from the stage.

In the UV light irradiation method according to a twelfth aspect of the disclosure, an irradiated-body moving portion is configured to move the irradiated body. A ball is arranged on a tip of the support pin. The irradiated body is moved with respect to the support pin when a force is applied from the irradiated-body moving portion to the irradiated body, and the irradiated body is moved on the ball.

In the UV light irradiation method according to a thirteenth aspect of the disclosure, an irradiated-body moving portion is configured to move the irradiated body. An air outlet is provided in a tip of the support pin. The irradiated body is moved with respect to the support pin by moving the irradiated body above the support pin when an air blown out from the air outlet applies a force from the irradiated-body moving portion to the irradiated body under a state in which the irradiated body is away from the support pin.

In the UV light irradiation method according to a fourteenth aspect of the disclosure, an air outlet is provided in a tip of the support pin. The ball includes a main ball and a plurality of auxiliary balls having a diameter smaller than that of the main ball. The plurality of auxiliary balls are arranged between the air outlet and the main ball. The plurality of auxiliary balls are rotated by an air blown out from the air outlet. The irradiated body is moved with respect to the support pin by rotating the main ball together with the rotation of the plurality of auxiliary balls.

In the UV light irradiation method according to a fifteenth aspect of the disclosure, the irradiated body is a light-transmissive substrate.

### REFERENCE SIGNS LIST

1 UV light irradiation device
10 Stage
12 Surface
20 Support pin
22 Pin tip portion
24 Ball receiver
25 Auxiliary ball (ball)
26 Main ball (ball)
28 Pin trunk portion
30 First irradiated-body moving portion
32 Second irradiated-body moving portion
34 Air outlet
40 UV light source
50 Irradiated body (light-transmissive substrate)
52 Irradiated region
100 UV light irradiation device
110 Stage
112 Surface
120 Support pin
122 Pin tip portion
128 Pin trunk portion
140 UV light source
150 Irradiated body
152 Irradiated region
154 Uneven part
Arrow A UV light
Arrow B Right-and-left direction
Arrow C Front-and-rear direction

1-13. (canceled)

14. The UV light irradiation method for irradiating an irradiated body with UV light, the method comprising:
arranging the irradiated body on a support pin or a stage;
supporting the irradiated body with the support pin and separating the irradiated body away from the stage; and
irradiating the irradiated body with UV light while moving the irradiated body with respect to the support pin under a state in which the irradiated body is away from the stage,
wherein an irradiated-body moving portion is configured to move the irradiated body,
a ball is arranged on a tip of the support pin,
the irradiated body is moved with respect to the support pin when a force is applied from the irradiated-body moving portion to the irradiated body, and the irradiated body is moved on the ball,
an air outlet is provided in the tip of the support pin,
the ball includes a main ball and a plurality of auxiliary balls having a diameter smaller than that of the main ball,
the plurality of auxiliary balls are arranged between the air outlet and the main ball,
the plurality of auxiliary balls are rotated by an air blown out from the air outlet, and
the irradiated body is moved with respect to the support pin by rotating the main ball together with rotation of the plurality of auxiliary balls.

15. The UV light irradiation method according to claim 14,
wherein the irradiated body is a light-transmissive substrate.

16. The UV light irradiation method according to claim 14,
wherein a difference of a UV light reflectance between a tip portion of the support pin and a surface of the stage is equal to or smaller than 1%.

17. The UV light irradiation method according to claim 14,
wherein a tip portion of the support pin and a surface of the stage are formed of the same material.

18. The UV light irradiation method according to claim 14,
wherein a tip portion of the support pin and a surface of the stage are subjected to similar surface processing.

19. The UV light irradiation method according to claim 18,
wherein the surface processing is anti-reflection processing with black plating.

20. The UV light irradiation method according to claim 14,
wherein the support pin and the irradiated body are prevented to be brought into contact with each other through intermediation of the air.
